(19) United States
(12) Patent Application Publication
(10) Pub. No.: US 2016/0163519 A1
(43) Pub. Date: Jun. 9, 2016

(54) METHOD AND APPARATUS FOR PLASMA IGNITION IN HIGH VACUUM CHAMBERS

(71) Applicant: XEI Scientic, Inc., Redwood City, CA (US)

(72) Inventors: Ronald A. Vane, Redwood City, CA (US); Michael Cable, Palo Alto, CA (US)

(21) Appl. No.: 14/982,260

(22) Filed: Dec. 29, 2015

Related U.S. Application Data
(63) Continuation of application No. PCT/US2014/059163, filed on Oct. 3, 2014.
Application No. PCT/US2014/059163 is a continuation-in-part of application No. 14/048,493, filed on Oct. 8, 2013.

(51) Int. Cl. H01J 37/32

(52) U.S. Cl. CPC H01J 37/32862; H01J 37/32082; H01J 37/32192; H01J 37/32449; H01J 37/32596; H01J 2237/335

(57) ABSTRACT

A new method and apparatus is described for igniting a plasma from high vacuum. The ignition method uses a small, short term and quick rise in gas flow into plasma chamber while being excited by RF power to ignite the plasma and then drops the gas flow to fixed input flow rate to maintain the plasma. This plasma starting technique does not use electronic means for ignition. The associated apparatus has a gas buffer chamber in fluid communication with the gas source and the plasma chamber, the gas buffer chamber having a small volume gas that is refilled when the device is off. A flow restriction between the gas source and the gas buffer chamber has a maximum flow rate therethrough of 30 sccm (standard cubic centimeters per minute) or less. A valve between the plasma chamber and the gas buffer chamber permits flow between the gas chamber and the plasma chamber, wherein, upon opening the valve, gas is admitted into the plasma chamber and pressure in the plasma chamber rises temporarily causing plasma ignition if the plasma excitation device is energized. The flow restriction maintains the gas flow during plasma operation to maintain a pressure between approximately 0.5 Pa and approximately 6-7 Pa.

### CROSS-REFERENCE TO RELATED APPLICATIONS

This application is a continuation of International Application PCT/U.S./2014/59163, designating the United States and led Oct. 3, 2014, which claims priority to and is a continuation-in-part of application Ser. No. 14/048,493 filed Oct. 8, 2013.

### TECHNICAL FIELD

The present invention relates to a new method and apparatus used to quickly ignite and start a non-equilibrium gas plasma. More particularly, the present invention is directed to such a method and apparatus for use in a high vacuum system that is pumped by a turbo-molecular pump and then after ignition maintains a low flow of working gas through the plasma at a rate that does not load and overheat the turbo-molecular pump. The resulting plasma operates at a low input flow rate to produce from the working gas active species such as neutral radicals, metastables, ions, free electrons, and UV and visible light while the turbo molecular pump continues to operate.

### BACKGROUND OF THE INVENTION

Plasma or a gas excited into electrically conductive ions and electrons is quite useful in plasma processing, producing excited species, producing light, and cleaning hydrocarbon and other contaminants from surfaces of vacuum instruments. It is known that at low vacuum gases become electrically conductive, and it is easiest to excite or ignite plasmas inside vacuum instruments. At atmospheric pressures plasma takes high power or heat to sustain. At high vacuum less than approximately 0.10 Pa (Pascal) there are not enough free electrons to sustain a plasma without magnetic confinement or other means.

To ignite and maintain a plasma, an electric field excites a gas to create ions and electrons to carry an electric current, and the plasma may emit light and create metastables and radicals. At low gas pressures, typically between 10 and 200 Pa, common gases such as air become conductive and plasmas are easy to ignite with relatively lower power. These pressures are easy to obtain with rough vacuum pumps such as the most commonly used rotary vane pumps. However these pumps have trouble achieving vacuums below 5 Pa.

Many kinds of vacuum instruments operate at pressures below 0.01 Pa. Plasmas may be sustained without a magnetic field in the mid vacuum range between approximately 10 and 0.1 Pa but are very hard to ignite. To achieve these lower pressures, it is now common to use turbo molecular pumps that can operate in the vacuum range between 5 Pa and 10⁻⁶ Pa. At these low pressures, it is difficult to ignite plasmas in part because of the reduced density of the gas and the lack of free electrons. Plasmas not aided by magnetic fields to confine electrons can operate in the upper ends of this pressure range but are difficult to ignite. Complex apparatus and methods may be needed to first adjust pressure levels at which plasma can be ignited easily and then re-evacuate the instrument to process pressures. To ignite plasma in mid vacuum, a source of free electrons, an ionization source, a pressure change, or a high electric field is needed, necessitating expensive additions to the instrument.

The difficulty igniting plasma consistently below 10 Pa usually requires an enhancement method. If the pressure is raised to an operating pressure greater than approximately 15 Pa and then the RF is turned on, the plasma will ignite reliably. The plasma may be ignited at a higher pressure above 15 Pa and the pressure lowered to 4 Pa or less for the cleaning operation. The previous technology used electronic pressure measurement and control to change the pressure between ignition and plasma states of operation or used a higher pressure greater than approximately 20 Pa so that the same pressure could be used for ignition and plasma operation.

The apparatus described in U.S. Pat. No. 6,105,589 to Vane was designed for use with oil diffusion high vacuum pumps. These pumps could not be exposed to the reactive gases made by the plasma or operated continuously at pressures above 1 Pa. Since year 2000 most electron microscopes have switched to the cleaner turbo molecular pumps (TMPs). These pumps can tolerate higher pressures and flow rates than that tolerated by diffusion pumps. They can overheat or suffer mechanical stress if sudden additional gas load is encountered or they are overloaded. Maximum flow and pressure specifications vary with manufacturer but gases flow of approximately 20 to 30 sccm or more are usually tolerated by modern turbo pumps for periods of 20 minutes or more.

### SUMMARY OF THE INVENTION

It is an object of the present invention to provide an improved method and apparatus for igniting a plasma at low pressures for plasma processing, excited species production, and cleaning vacuum chambers. In particular, the present invention is concerned with igniting plasma adjacent to the specimen chamber, to clean the specimen stage and a specimen in the vacuum system of an electron microscope or similar analytical instrument that uses an electron beam such as a scanning electron microprobe instrument or focused ion beam instrument.

It is another object of the present invention to provide a method for cleaning said instruments that can be operated at lower pressures than conventional plasma methods thus alleviating the need to either raise the pressure to above 10 Pa or to provide electrical stimulation.

It is another object of the present invention to provide a cleaning system that is small and can be mounted on a standard chamber port of the electron microscope without mechanical interference from other devices and parts of the electron microscope.

It is another object of the present invention to provide a plasma cleaning system that can use room air as the source of oxygen to be converted by the plasma into oxygen radicals for oxidative cleaning.

It is another object of the present invention to provide a plasma system that can be operated with gases such as O₂, N₂, air, Ar, He, H₂O, H, NH₃ and mixtures thereof.

It is another object of the present invention to control the gas flow into a plasma with a single valve that is either open or closed and without using an integrated pressure gauge to monitor pressure. The result is a very simple plasma cleaning system.

It is another object of the present invention to provide a plasma cleaning system that comprises a small RF plasma chamber that can be operated at 50 Watts or less of forward RF power, a gas dosing device to deliver a quantity of reactant gas for plasma ignition and a flow restrictor to limit the gas flow into the plasma once ignited to a low rate that allows continuous plasma operation without pump damage or overheating and gives high plasma cleaning rates and range. The flow constrictor may be an orifice, a manual needle valve, or a valve capable of selectable variable gas conduction controlled via a programmed signal to induce a predetermined pressure versus time response in the plasma chamber.

It is yet another general object of the present invention to provide a method for cleaning such instruments that can be operated at pressures less than 5 Pa, thus alleviating the need to maintain the pressure above 5 Pa after plasma ignition,

Another object of the present invention is to eliminate the need for active monitoring of pressure and control of gas flow into the plasma.

These and other objects of the present invention are achieved by providing a simplified method of igniting a plasma in a high vacuum chamber when the density of gas is otherwise not enough to provide the conductivity to start a plasma with the power applied. The apparatus of the present invention applies a small pulse of gas into a small plasma chamber attached to the vacuum chamber while power is supplied or simultaneously with the application of power into the plasma chamber, resulting in the plasma ignition during the rise to a higher pressure followed by the maintenance of the vacuum at a lower pressure governed by a small leak or flow of working gas into the plasma chamber.

In the first embodiment of the present invention the apparatus may comprise a small gas volume located between a gas admission valve on a small plasma chamber and a gas flow restrictor. The restrictor limits the flow of gas into the small gas volume to a set value when the gas admission valve is open. While the gas admission valve is open, pressure in the plasma and vacuum chambers remains at a level that will support plasma maintenance.

When the gas admission valve is closed, the pressure in the small gas volume will slowly equalize with the inlet pressure which in most cases will be atmospheric pressure or approximately 10⁵ Pa.

In a second embodiment of the present invention the apparatus may comprise of a variable leak valve such as programed mass flow controller or a simple manually operated needle valve that is quickly opened and then reduced to achieve the desired pressure rise and then stabilization at the operating flow rate for plasma operation

### BRIEF DESCRIPTION OF THE DRAWINGS

FIG. 1 is a schematic depiction of the apparatus of the present invention connected to a vacuum chamber.

FIG. 2 is a pressure-and-time diagram showing the relationship of the before chamber pressure, plasma ignition pressure, steady state plasma pressure, and post plasma pressure.

FIG. 3 shows a preferred embodiment with a hollow cathode electron for RF plasma cleaning of electron microscopes.

FIG. 4 is a graph of the concentration of oxygen radicals as a function of residence time at various pressures using the apparatus and method of the present invention.

### REFERENCE NUMBERS IN FIGURES

1 Small plasma chamber
2 Vacuum chamber
4 Vacuum (Turbo Molecular) Pump
6 Valve
8 Gas manifold
10 Gas orifice
12 Gas buffer chamber
14 Gas source
16 Plasma exciter
20 Hollow cathode
22 Impedance matching network
24 Gas valve connector
30 Gas burst point
32 Baseline level
34 Plasma cleaning period
36 Plasma off point
38 Pressure range

### DETAILED DESCRIPTION OF THE INVENTION

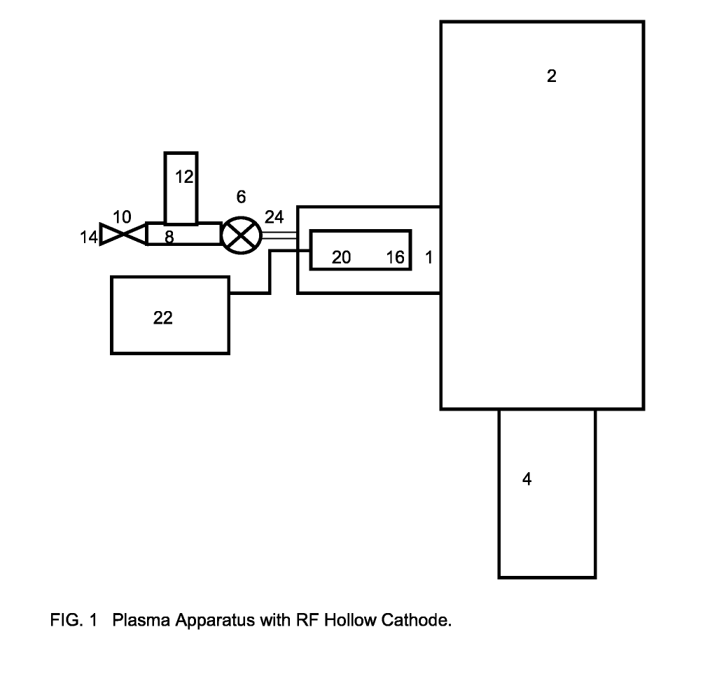

FIG. 1 schematically illustrates preferred embodiment of the apparatus according to the present invention. A small plasma chamber 1 is attached in fluid communication with the main vacuum chamber 2 of an analytical instrument. As mentioned, the present invention is particularly concerned with the specimen chamber of an electron microscope or similar analytical instrument using an electron beam such as a scanning electron microprobe instrument or focused ion beam instrument. Accordingly, main vacuum chamber 2 is the sample chamber of such an instrument.

Main vacuum chamber 2 is connected to a turbo-molecular pump (TMP) 4, which is used to evacuate or draw a vacuum in chamber 2. Chamber 2 will maintain a steady pressure known as the base pressure when being pumped by the TMP. An electronically controlled open/close valve 6 is connected to small plasma chamber 1 via a gas valve connector 24 at the end opposite main vacuum chamber 2. Valve 6 controls (in a binary fashion) the flow of a gas into small plasma chamber 1 from a gas manifold 8 and hollow cylindrical gas buffer chamber 12, which is in turn coupled to a flow restriction or restrictor in the form of a needle valve or gas orifice plate 10, that permits a tiny volume of gas per minute (referred to as a “leak”) to flow into manifold 8 and a gas buffer 12 from a gas source 14. In some instances, the gas can be air, and the source can simply be the atmosphere, with proper filtering. The “leak” is an amount or volume flow rate that is sufficiently small that TMP 4 can pump the leaked volume out of main vacuum chamber 2 without overheating, while also providing sufficient gas pressure and volume to permit ignition of the plasma. Preferably, the maximum leak flow rate is no more than approximately 30 sccm (cc/minute at standard temperature and pressure) as this is the amount of leak flow rate that can be sustained by conventional TMPs without overheating.

The combined volume of manifold 8 and buffer chamber 12 is approximately 1/500 to 1/10,000 and preferably 1/5000 the volume of main vacuum chamber 2. Gas buffer 12 and manifold 8 store a volume of gas at approximately atmospheric pressure (higher pressure is undesirable because it would reduce the vacuum in the system too drastically) for “burst” flow into small plasma chamber 1 upon opening of valve 6. An exemplary volume of main chamber 2 is 10 liters, the combined volume of the manifold and buffer chambers preferably is 2 milliliters. The flow rate through flow restriction 10 is preferably approximately 20 sccm (cc/minute at standard temperature and pressure) for TMPs of medium pumping capacity (of approximately 200 l/sec).

The small plasma chamber 1 contains the plasma that is excited electrically using a DC, AC, High frequency, RF, or microwave power source. A plasma exciting device 16 may be a microwave cavity, contain internal electrodes 20, or be within or adjacent to an ICP (inductively couple plasma) coil including an ICP excited Toroidal Plasma source, and is energized for plasma ignition or excitation by electric power. An impedance matching network 22 may be needed to match the power source and the load to couple the maximum power into the plasma. The small chamber 1 is directly fluidly connected to main chamber 2 so that the plasma activated gas may flow into the main chamber without restriction.

The method of operation of the present invention includes the steps of pumping the main chamber 2 with the TMP 4 to a vacuum of less than 1 Pa. The plasma is started by turning on the plasma power to plasma exciter 16 in small plasma chamber 1 before or simultaneously with the opening of the gas control valve 6. This releases the volume of gas stored in the gas buffer chamber 12 between the input gas valve 6 and the gas leak 10 into the plasma chamber 1 and vacuum chamber 2. This gas is stored at the input gas pressure typically equal to atmospheric pressure (−10⁵ Pa) when the gas valve 6 is closed. This gas causes a quick rise in pressure or a “burst” in plasma chamber 1. This rise in pressure causes the plasma to ignite at a lower pressure than can be used when the plasma power is applied at static pressure. Because the volume of the storage chamber is approximately 1/5000 the volume of the vacuum chamber, opening the valve 6 will raise the pressure of the vacuum chamber 2 briefly before the gas is removed by TMP 4. After plasma ignition Valve 6 remains open but the pressure drops to the plasma operating pressure while plasma is being generated and while a leak aperture needle valve or orifice 10 supplies gas to plasma chamber 1, but due to its tiny gas throughput, does not allow enough gas flow to overload and overheat the turbo-molecular pump, the pressure then drops and the plasma pressure is maintained in an operating range of between approximately 0.5 and 3 Pa for plasma operation (i.e. maintenance of ignited or excited plasma—once plasma is ignited during the pressure burst it can be sustained at lower pressures).

This burst of gas has sufficiently fast rise time at sufficient pressure to allow the plasma source to ignite the plasma in the small plasma chamber 1. The plasma can then be maintained as TMP 4 re-evacuates the vacuum chambers 2, 1 down to a plasma operating pressure. The flow rate out of chamber 1 into chamber 2 at steady state will be equal to the input after the ignition pressure burst and the pressure in chamber 1 will be a function of the base pressure of the chamber and the input flow and the size of the port between chamber 1 and 2. This flow out of the plasma chamber 1 will be in molecular flow and will not be affected by the size of the vacuum pump evacuating chamber 2. Therefore plasma operating pressure in the plasma chamber will only vary by the base pressure of chamber 2 if the pumping speed is sufficient to maintain the pressure below approximately 0.5 Pa. Typically this pressure will be above approximately 0.5 to 7 Pa and the plasma operation will be maintained as long as both the plasma power and the gas flow are on. The leak rate of the orifice should be selected to maintain a pressure against the evacuation rate of the vacuum pump that keeps the plasma on and conducting, but low enough that the high vacuum turbo molecular pump is not over heated during the plasma operation time.

In the preferred embodiment the gas buffer chamber 12 stores the small gas volume needed to create the pressure burst. Our research has shown that ignition is not achieved by the maximum pressure achieved in the burst, but by the fast rate of rise in pressure. After plasma ignition, the small gas buffer chamber 12 will drop in pressure and will be supplied with gas for the plasma through the gas flow restrictor. The gas flow rate through the restrictor is chosen so that the pressure in the small plasma chamber 1 is above 1 Pa and in the main vacuum chamber 2 is below 6 Pa. The 1 Pa minimum in the plasma chamber is chosen because it becomes difficult to maintain plasma conduction without magnetic confinement at lower pressure. The approximate 6 Pa upper limit for the large chamber is caused by the sharp drop in residence time due to the increased collision rates and shorter mean free path that cause a rapid decline in cleaning ability as the pressures rises into the conventional plasma cleaning range. The Pressure of 6 Pa also marks the approximate upper pressure of improved cleaning ability of the present invention.

There is another upper limit placed on the pressure of approximately 4 Pa caused by the possible heating of the turbo molecular pump with high higher gas loads. This pressure upper limit varies with the design of the turbo molecular pump. Some Turbo molecular pumps are designed for higher input pressures or flow rates without overheating problems. For these pumps continuous operation a continuous gas load of up to approximately 25-30 sccm or input pressure of 76 Pa or greater may be tolerated per manufacturer's specification. Small bursts of gas as provided by the present invention are tolerated by the turbo molecular pump, but do cause some momentary mechanical stress. This upper limit varies with the model and make of the turbo molecular pump.

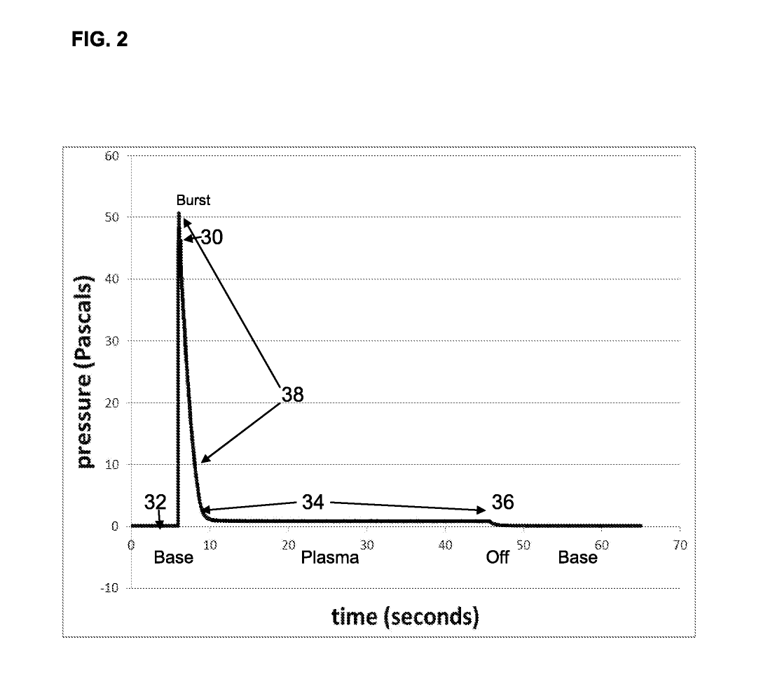

FIG. 2 shows a plot of pressure, time, and period of plasma operation. When the plasma is not needed, both the power and gas (valve 6) are turned off. Before the pressure burst the vacuum is at the baseline level 32 which is typically less than approximately 0.10 Pa when pumped by TMP. With the RF power applied either before or simultaneously with the opening of gas valve 6 (FIG. 1), the gas burst 30 is created in the pressure range 38 typically above 2 Pa, and plasma ignition results. The pressure then drops into the plasma cleaning period 34 until the gas flow and plasma power are turned off (by cutting power to plasma exciter 16 and closing valve 6) at point 36. With the gas flow off the pressure will return to the base pressure 32 or below. A lower base pressure will occur if the plasma cleaning process removes contamination that had a significant partial pressure.

Experiments were done to demonstrate that the high rate of pressure rise of the burst of gas and not the higher pressure in the burst was responsible for ignition, and this data was taken: For a hollow cathode type device at an operating power of 10 Watts, ignition could be done at 11 Pa in a static pressure mode and in burst mode ignition was at at 2.7 Pa. At 20 watts, static pressure ignition was achieved at 7.1 Pa and in burst mode ignition was at 2.2 Pa. In both cases the measured rise time from pressure below 10-⁶ Pa to 6 Pa was less than 27 milliseconds, for a pressure rise rate of faster than 200 Pa per second. The operating pressure after ignition was found to be 1.5 Pa in the plasma with a 20 sccm input flow rate of room air in all cases. This with done with a carefully tuned impedance match network to get the lowest possible ignition pressure with the apparatus of the present invention. This data proved that the rise rate and not the static pressure aided the ignition of the plasma. It is believed that the pressure rise must occur within less than 100 milliseconds and at a rate exceeding 100 Pa/s

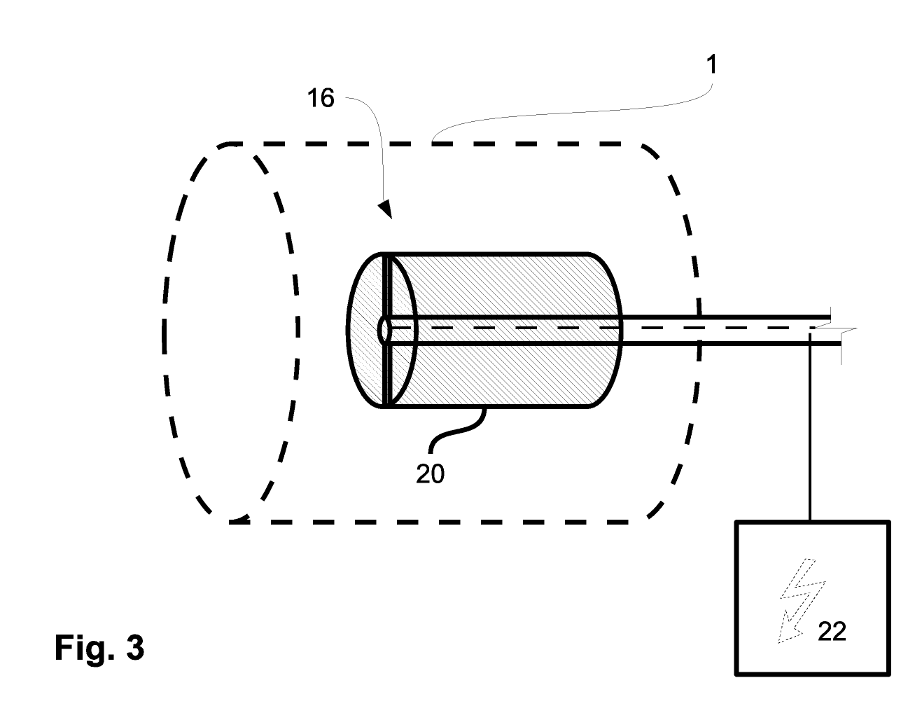

In the preferred embodiment of the apparatus of present invention, the plasma exciter (16 in FIG. 1) is a hollow cathode RF plasma device as shown in FIG. 3. The resulting plasma is used to produce radicals to clean electron microscopes or other charge beam instruments. The plasma excitation is done by a hollow cylindrical cathode electrode 20 placed inside the small plasma chamber 1 to excite the plasma. The gas source inlet 24 is located (FIG. 1) such that the gas flows inside the hollow cathode cylinder 20. The gas source inlet is connected to the inlet valve 6 and to manifold 8 and baffle 12. RF power is supplied to the hollow cathode 20 in this embodiment. The gas can be air, oxygen, or other oxygen-containing gases or gas mixtures such as water vapor, oxygen argon, oxygen and helium, and other nitrogen plus oxygen mixtures for oxidative cleaning. Alternately, hydrogen, hydrogen and nitrogen mixtures, or ammonia-containing gases could be used for reduction cleaning.

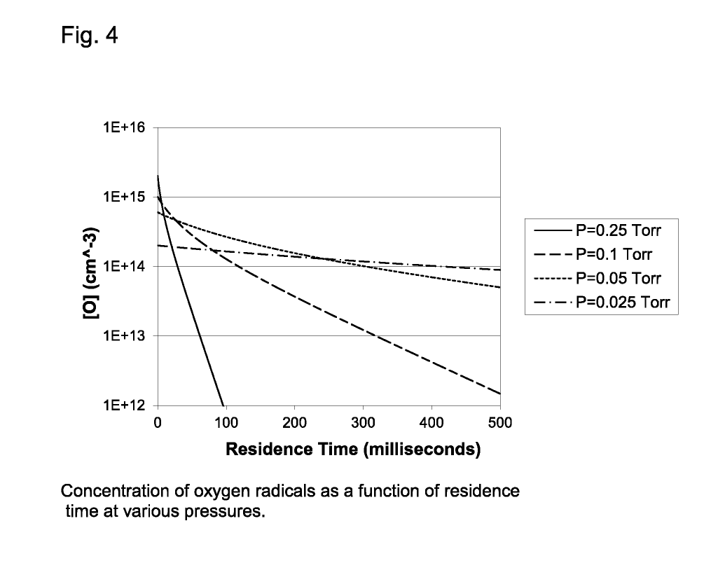

When the RF power is on, a plasma is excited inside hollow cathode 20 to produce the desired radicals. The radicals then flow into vacuum chamber 2 which is the imaging chamber of an electron microscope or other instrument that needs to be cleaned. The RF power source is typically 13.56 MHz but other frequencies may be used. An impedance match network 22 will be needed to transfer the maximum power to the plasma load. The desired plasma pressure is between approximately 0.5 Pa and approximately 4 Pa inside small plasma chamber 1 and differential pumping will result in a lower pressure in the main vacuum chamber. Pumping is done by a TMP 4. This pressure range is desired because there is enough gas density to support sustained plasma and there is a long enough mean free path for a long collision free lifetime for the radicals. See FIG. 4 for a chart of O₂ radical lifetimes vs pressure. When air is the plasma gas, a flowing afterglow from the decay of metastables and radicals is observed in this pressure range indicating the presence of excited atomic and molecular states. This accompanies the higher cleaning rates and larger cleaning volumes than those obtained at higher pressures. Using quartz crystal monitors there is measureable cleaning measured at 55 cm from the plasma at 20 mTorr while there is almost zero cleaning at this distance at 400 mTorr.

The previous technology used electronic pressure measurement and control to change the pressure between ignition and plasma states of operation or used a higher pressure above approximately 20 Pa to so that the same pressure was used for ignition and plasma operation. In the present invention the gas valve is opened to provide a gas burst either simultaneously or after the plasma power is turned on. With a typical vacuum chamber 2 volume of 10 liters, the storage gas volume in the manifold 8 and gas buffer chamber 12 should be between 1 and 10 ml. This will provide a burst of gas to ignite plasma with the pressure rising temporarily and within about 100 milliseconds as the RF power turns on. With a typical leak rate of 20 sccm (cubic centimeters/minute at standard pressure and temperature) through the gas leak device, and pumping with a typical small—medium sized turbo pump, the pressure will then fall to less than approximately 7 Pa in the small vacuum chamber and the plasma will be sustained to produce cleaning species.

In a second embodiment of the present invention valve 6 and the gas buffer chamber are replaced with a variable valve that is either manually or electrically adjusted to produce a gas burst to ignite the plasma. The valve is capable of selectable variable gas conduction and may be controlled via a programmed signal to induce a predetermined pressure versus time response in the plasma chamber. Examples of such valves include proportional control valves and mass airflow controllers, both of which can be precisely electronically controlled as to opening, closing, and flowrate therethrough.

FIG. 4 shows the concentration of oxygen radicals against residence time at various pressures. The data was calculated in Torr rather than Pa.

### Conversion Factors:

0.75 Torr=100 Pa
0.25 Torr=33Pa
0.1 Torr=1.3 Pa
0.05 Torr=6.7 Pa
0.025 Torr=3.3 Pa
   Cleaning large chambers with radicals requires that the radicals have long residence time in the chamber so that they can reach locations far away (−1 m) from the radical source. Destruction of radicals can occur by wall collisions and also by gas phase reactions. These reactions are pressure dependent, especially three-body reactions, which are the most likely means of radical destruction. If the pressure in the chamber is kept low, mean free paths are increased, the three-body reaction rates will be decreased and the residence time of the radicals will increase. This behavior can be demonstrated by a simple kinetics model using literature values for reaction rates. A decrease in pressure leads to a decrease in the number of radicals created by the plasma, but the rate of radical destruction as a function of residence time dramatically decreases. As seen in FIG. 4, at 0.25 Torr chamber pressure, the radical concentration decreases by 1000× in 100 milliseconds, but at 0.025 Torr, it will take over 400 milliseconds for the radical concentration to decrease by 2×. Thus lower plasma pressures improve the cleaning ranges and cleaning rates of oxygen radicals.

These improvements result in a cleaning system that can be started when the chamber is at high vacuum and the turbo molecular pump is rotating at full speed. As a result of being at higher vacuum these improvements result in a cleaning system that is faster and cleans the specimen chamber, stage, and specimen of the analytical instrument such as an electron microscope better than previous arrangements. The result of a cleaner specimen, specimen chamber and stage is that the deposition of hydrocarbon polymer on the scanned area is reduced or eliminated resulting in more accurate measurements.

Another benefit of cleaner specimen chambers is that the condensation and adsorption of hydrocarbons on detector windows is reduced which allows the passage of more low energy x-rays and electrons through these windows. Additionally, in other high vacuum systems the removal of carbon results in a lower partial pressure of carbon compounds without the use of baking or long pumping times.

The invention has been described with reference to preferred embodiments thereof, it is thus not limited, but is susceptible to variation and modification without departing from the scope of the invention.

In the claims:

1. A plasma processing apparatus for use with a vacuum instrument having a vacuum chamber of selected volume and said vacuum volume evacuated by a high vacuum pump to a pressure below a 1 Pa, the plasma cleaning apparatus comprising:
a plasma chamber in fluid communication with the vacuum chamber;
a plasma excitation device contained in the plasma chamber;
a gas chamber in fluid communication with the plasma chamber, the gas chamber having a volume approximately 1/500 to 1/50,000 of the selected volume of the vacuum chamber;
a valve between the plasma chamber and the gas chamber, the valve selectively permitting flow between the gas chamber and the plasma chamber;
a gas source in fluid communication with the gas chamber; and
a flow restrictor between the gas source and the gas chamber, the flow restrictor limiting the gas flow into the gas chamber to less than about 30 sccm (standard cubic centimeters per minute) to minimize heating in the vacuum pump, wherein, with the plasma excitation device energized, the valve is opened, pressure in the plasma chamber rises at a rate sufficient to enable plasma ignition, and then the gas pressure in the plasma chamber drops to a pressure sufficient to maintain a plasma while the valve remains open admitting gas after plasma ignition.

2. The plasma processing apparatus of claim 1, wherein the high vacuum pump is a turbo-molecular pump.

3. The plasma processing apparatus of claim 1, wherein the plasma excitation device is a hollow cathode powered by radio frequency electricity at 13.56 MHz.

4. The plasma processing apparatus of claim 1, wherein the flow restrictor is an orifice plate.

5. The plasma processing apparatus of claim 1, wherein the flow restrictor is a needle valve.

6. The plasma processing apparatus of claim 1, wherein the flow restrictor is provided by a mass flow controller.

7. The plasma processing apparatus of claim 1, wherein the plasma is used for plasma cleaning of the vacuum chamber and surfaces therein.

8. The plasma processing apparatus of claim 6, wherein the gas is selected from O₂, N₂, room air, Ar, He, H₂O, H, NH₃ and mixtures thereof.

9. The plasma processing apparatus of claim 1, wherein the pressure sufficient to maintain a plasma is between approximately 0.5 Pa and 7 Pa.

10. The plasma processing apparats of claim 1 where the valve has variable and selectable gas conduction, and is controlled to result in a programmed plasma chamber pressure as a function of time.

11. The plasma processing apparatus of claim 10 wherein the valve is a mass-flow controller.

12. The plasma processing apparatus of claim 10 wherein the valve is a proportional control valve.

13. The plasma processing apparatus of claim 1 wherein the rise of pressure in the plasma chamber occurs at a rate greater than about 100 Pa/second in 100 milliseconds or less.

14. A method of igniting a plasma in a plasma chamber including a plasma excitation device to operate on a vacuum chamber that is actively pumped to a pressure less than 6 Pa, the plasma chamber being in fluid communication with the vacuum chamber , the method comprising the steps of:
supplying electric power to the plasma excitation device in suitable form for exciting a plasma,
admitting a selected volume of gas into the plasma chamber to temporarily raise pressure in the plasma chamber at a rate sufficient to aid in ignition of the plasma, and
after ignition of plasma, flowing gas through the plasma chamber at a flow rate sufficient for maintaining an operational pressure range in the plasma chamber while the plasma excitation device is energized

15. The method of claim 14, wherein the operational pressure range is between approximately 0.5 and 7 Pa.

16. The method of claim 14, wherein the step of supplying electric power to the plasma exitation device comprises supplying a hollow cathode in the plasma chamber with radio frequency electricity at approximately 13.65 MHz.

17. The method of claim 14, wherein the step of admitting a volume of gas into the plasma chamber comprises opening a valve between the plasma chamber and a gas chamber containing the gas and having a volume between 1/500 and 1/50,000 that of the vacuum chamber.

18. The method of claim 14, wherein the gas is selected from O₂, N₂, air, Ar, He, H₂O, H, NH₃ and mixtures thereof.

19. The method of claim 14, wherein electric power in suitable form for exciting a plasma includes DC, AC, High frequency, RF, and microwave power and the plasma exciting device may be selected from a microwave cavity, contain internal electrodes, or be within or adjacent to an ICP.

20. The method of claim 14 wherein pressure rises in the plasma chamber at a rate of at least 100 Pa/s in 100 milliseconds or less.

21. A plasma cleaning apparatus for use with a vacuum instrument having a vacuum chamber of selected volume that may be evacuated by an oil free high vacuum pump such as a turbo-molecular pump to a base pressure below approximately 1 Pa, the plasma cleaning apparatus comprising:
a plasma chamber in fluid communication with the vacuum chamber;
a plasma excitation device contained in the plasma chamber;
a gas chamber in fluid communication with the plasma chamber, the gas chamber having a volume between 1/500 to 1/50000 of the selected volume of the vacuum chamber;
a valve between the plasma chamber and the gas chamber, the valve selectively permitting flow between the gas chamber and the plasma chamber, wherein, upon opening the valve, gas is admitted into the plasma chamber and pressure in the plasma chamber rises and falls such that plasma ignition is obtained when the plasma excitation device is energized,
a gas source in fluid communication with the gas chamber; and
a flow restriction between the gas source and the gas chamber, the flow restriction having a maximum flow rate therethrough of less than approximately approximately 30 sccm. (standard cubic centimeters per minute) so that pressure in the plasma chamber remains sufficient after plasma ignition to maintain plasma conduction and to avoid overloading or heating of the high vacuum pump.

22. The plasma cleaning apparatus of claim 21, wherein the plasma exciter is a hollow cathode powered by radio frequency electricity at 13.56 Mz MHz.

23. The plasma cleaning apparatus of claim 21, wherein the flow restrictor is an orifice plate.

24. The plasma cleaning apparatus of claim 21, wherein the flow restrictor is a needle valve.

25. The plasma cleaning apparatus of claim 21, wherein the gas is selected from O₂, N₂, air, Ar, He, H₂O, H, NH₃ and mixtures thereof.

26. The plasma cleaning apparatus of claim 21, wherein pressure is maintained in the plasma chamber between approximately 0.5 Pa and approximately 7 Pa after plasma ignition.

27. The plasma cleaning apparatus of claim 21 where the valve has variable and selectable gas conduction, and is controlled to result in a programmed plasma chamber pressure as a function of time.

28. The plasma cleaning apparatus of claim 27 where the valve is a mass-flow controller.

29. The plasma cleaning apparatus of claim 27 where the valve is a proportional control valve.

30. The plasma cleaning device of claim 21 wherein the rise of pressure in the plasma chamber is greater than 100 Pa/second in 100 milliseconds or less
